(19) United States
(12) Patent Application Publication
(10) Pub. No.: US 2006/0193409 A1
(43) Pub. Date: Aug. 31, 2006

(54) Method and apparatus for compensation of doppler induced carrier frequency offset in a digital receiver system

(76) Inventors: Shaohan Joe Chou, Marlboro, NJ (US); Min Liang, Morganville, NJ (US); Steven C. Pinault, Allentown, PA (US); Jinguo Yu, Flemington, NJ (US)

Correspondence Address: RYAN, MASON & LEWIS, LLP, 1300 POST ROAD, SUITE 205, FAIRFIELD, CT, 06824, US

(21) Appl. No.: 11/068,512

(22) Filed: Feb. 28, 2005

(51) Int. Cl. H03D 1/04

(52) U.S. Cl. 375/346

(57) ABSTRACT

Methods and apparatus are provided for compensating for Doppler induced carrier frequency offset in a digital receiver. According to one aspect of the invention, a received signal is digitized and a differential detection algorithm is applied to the digitized received signal to compensate for the Doppler induced carrier frequency offset. A symbol timing recovery algorithm can also be applied to the digitized received signal to compensate for symbol timing offset.

### FIELD OF THE INVENTION

The present invention relates generally to digital communication receivers, and more particularly, to techniques for compensating for Doppler frequency shifts in such digital communication receivers.

### BACKGROUND OF THE INVENTION

Doppler induced carrier frequency offset is a common impairment in mobile wireless communication systems. Doppler frequency shift results in a drift in the carrier frequency and the symbol frequency of a mobile digital receiver system, which in some operating environments causes a significant degradation in receiver performance. Currently, such Doppler frequency shift is mitigated using a carrier recovery algorithm that compensates for the drift in carrier frequency, followed by a timing recovery algorithm that compensates for symbol timing offset and a phase recovery algorithm that compensates for a constant yet unknown phase shift due to the distance between the transmitter and the receiver.

While the carrier recovery algorithm effectively compensates for carrier frequency drift, the complexity of the carrier recovery algorithm unnecessarily increases the cost and complexity of TDMA digital receivers. A need therefore exists for an improved and less computationally intensive method and apparatus that compensate for Doppler induced carrier frequency offset in TDMA digital mobile receivers.

### SUMMARY OF THE INVENTION

Generally, methods and apparatus are provided for compensating for Doppler induced carrier frequency offset in a digital receiver. According to one aspect of the invention, a received signal is digitized and a differential detection algorithm is applied to the digitized received signal to compensate for the Doppler induced carrier frequency offset. A symbol timing recovery algorithm can also be applied to the digitized received signal to compensate for symbol timing offset.

A more complete understanding of the present invention, as well as further features and advantages of the present invention, will be obtained by reference to the following detailed description and drawings.

### BRIEF DESCRIPTION OF THE DRAWINGS

FIG. 1 is a schematic block diagram of a conventional TDMA digital mobile receiver system; and

FIG. 2 is a schematic block diagram of a TDMA digital mobile receiver system incorporating features of the present invention.

### DETAILED DESCRIPTION

The present invention applies a differential detection technique as a pre-processing step that mitigates the effects of Doppler induced carrier frequency offset, so that only the symbol timing recovery algorithm is required for Doppler offset compensation. According to one aspect of the invention, the differential detection pre-processing reduces the phase drift caused by carrier offset to a constant value consisting of the phase offset of a single symbol period, thereby achieving the carrier frequency offset compensation objective. Thus, the Doppler compensation task is reduced to only compensating for symbol timing offset.

The present invention recognizes that in differential Phase Shift Keying (PSK) TDMA mobile phone systems, such as PHS (Personal Handy Phone System) and Interim Standard 136 (IS-136; also referred to as “Digital AMPS”), the Doppler shift is generally relatively small with respect to the system transmission data rate (ƒ_{d}<<ƒ_{symb}). In this manner, a differential detection technique can pre-process the input signals to reduce the Doppler carrier frequency shift to a constant phase shift corresponding to the shift in a single symbol period (which can normally be ignored).

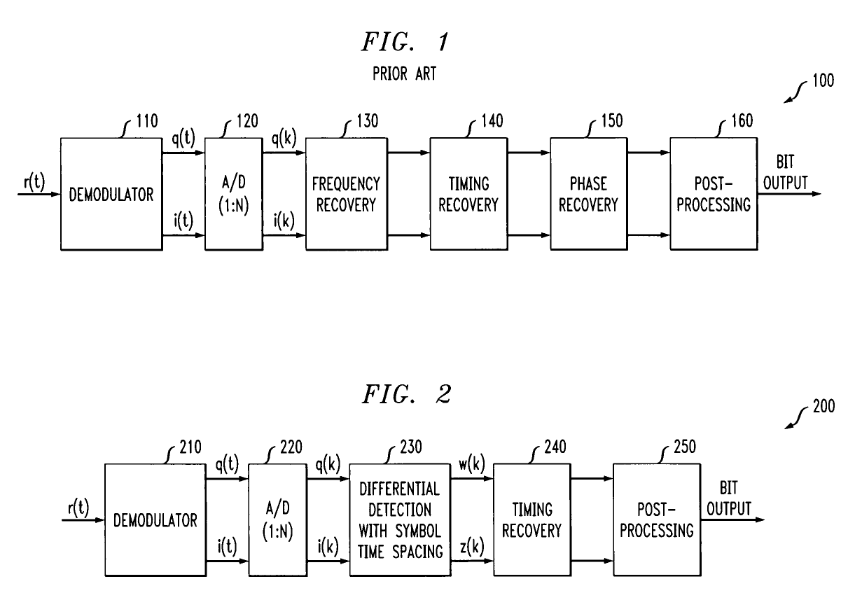

FIG. 1 is a schematic block diagram of a conventional TDMA digital mobile receiver system 100. As shown in FIG. 1, the exemplary TDMA digital mobile receiver system 100 is a differential PSK TDMA mobile receiver. The received RF signal, r(t), can be expressed as (ignoring the noise term for convenience):
r(t)=I(t)·cos {2π(ƒ_{c}+ƒ_{d})t−φ}−Q(t)·sin {2π(ƒ_{c}+ƒ_{d})t−φ}. (1)
Here, f_{c} is the carrier frequency, f_{d} is the Doppler carrier frequency shift due to the motion between the transmitter and the receiver, φ is a constant phase shift due to the distance between the transmitter and the receiver, and r(t) is normalized, i.e., I²(t)+Q²(t)=1.

After demodulation at stage 110, the baseband signals for in-phase and quadrature-phase can be expressed as:
i(t)=I(t)·cos (2πƒ_{d}t−φ) (2)
q(t)=Q(t)·sin (2πƒ_{d}t−φ) (3)

Thereafter, the i(t) and q(t) signals are each sampled by an Analog to Digital Converter (A/D) 120 with a sampling rate of N times the symbol rate. Following this is the carrier frequency recovery circuit 130 to remove the Doppler carrier frequency shift and then the recovered samples are further processed by a symbol timing recovery algorithm 140 and a phase recovery algorithm 150, as well as additional post-processing 160, such as equalization, demapping, descrambling, and decoding to get the final output. For a more detailed discussion of the conventional TDMA digital mobile receiver system 100, see, for example, Theodore Rappaport, Wireless Communications: Principles and Practice (2001), incorporated by reference herein.

FIG. 2 is a schematic block diagram of a TDMA digital mobile receiver system 200 incorporating features of the present invention. As shown in FIG. 2, the TDMA digital mobile receiver system 200 of the present invention uses differential detection to compensate for the Doppler shift f_{d} and unknown phase φ and hence simplify the receiver structure (relative to the TDMA digital mobile receiver system 100 of FIG. 1).

As shown in FIG. 2, the received signal is initially demodulated at stage 210 and digitized by Analog to Digital Converter (A/D) 220, in a similar manner to FIG. 1. After A/D sampling, the digitized signals can be expressed as follows:
i(k)=I(tₖ)·cos (2πƒ_{d}tₖ−φ) (4)
q(k)=Q(tₖ)·sin (2πƒ_{d}tₖ−φ) (5)

According to the present invention, the differential detection approach is then applied at stage 230 to pre-process i(k) and q(k) with symbol time interval spacing as follows:
z(k)=i(k)·i(k−N)+q(k)·q(k−N) =cos {2πƒ_{d}/ƒ_{symb}+Δθ(k)} (6)
w(k)=i(k−N)·q(k)−i(k)·q(k−N) =sin {2πƒ_{d}/ƒ_{symb}+Δθ(k)} (7)
where f_{symb} is the symbol rate, N is the number of samples per baud, and Δθ(k) is the phase transition between the sample in the current symbol and the corresponding sample in the immediately preceding symbol, which contains the transmission bit information for a differential PSK system. For a more detailed discussion of the differential detection approach applied during stage 230, see, for example, Theodore Rappaport, Wireless Communications: Principles and Practice, Ch. 6 (2001), incorporated by reference herein.

Since ƒ_{d}/ƒ_{symb}<<1 for TDMA mobile phone systems, equations (6) and (7) simplify to:
z(k)=cos {Δθ(k)} (8)
w(k)=sin {Δθ(k)} (9)

Equations (6) and (7) show that the unknown phase is eliminated and the Doppler shift f_{d} is reduced to a constant phase offset. For Doppler shifts that are small relative to the symbol frequency, equations (8) and (9) show that the Doppler shift f_{d} and unknown phase φ are both compensated.

As shown in FIG. 2, following differential detection 230, the recovered samples are further processed by a symbol timing recovery algorithm 240, as well as additional post-processing 250, such as equalization, demapping, descrambling, and decoding to get the final output, in the manner described above in conjunction with FIG. 1.

In an environment with only minor intersymbol interference (ISI), and for a data frame short enough that the amount of symbol timing offset that would accumulate in one frame can be ignored, the transmitted bit information can be recovered directly from the outputs z, w of equations (8) and (9), respectively. The only post processing 250 needed is the demapping, descrambling and differential decoding. Thus, in such a system the differential detection module 230 is actually used as the main module of the receiver.

The present invention recognizes that the differential detector can be used as a pre-processor in those situations where the differential detector alone will not function as a receiver. If there is sufficient ISI or accumulated symbol timing offset to require the use of an equalizer or a timing recovery algorithm, then the differential detector by itself will fail and a coherent detector as shown in FIG. 1 is typically used instead. In the present invention, the differential detector is retained as a pre-processor in such a case. Symbol timing recovery 240 is applied to the pre-processed samples z(k) and w(k), and then the timing recovery output samples are passed to the post-processing module to get the final bit stream output. The post processing module 250 will contain, as before, operations such as equalization, demapping, descrambling, and decoding.

The TDMA digital mobile receiver system 200 of the present invention replaces the frequency and phase recovery circuits 130, 150 which are required in a conventional TDMA mobile phone system 100 with a differential detection operation 230 resulting in lower complexity and cost. Among other benefits, the differential detection pre-processing of the present invention reduces the real time signal processing requirements and hence increases the battery life for the receiver.

It is to be understood that the embodiments and variations shown and described herein are merely illustrative of the principles of this invention and that various modifications may be implemented by those skilled in the art without departing from the scope and spirit of the invention.

We claim:

1. A method for compensating for frequency offset in a received signal, comprising:
digitizing said received signal; and
applying a differential detection algorithm to said digitized received signal.

2. The method of claim 1, wherein said step of digitizing said received signal further comprises the step of demodulating said received signal to generate baseband signals for in-phase and quadrature-phase components.

3. The method of claim 1, wherein said frequency offset compensation corrects for a Doppler shift.

4. The method of claim 1, wherein said step of applying a differential detection algorithm further comprises the step of pre-processing said digitized received signal i(k) and q(k) with symbol time interval spacing as follows:
z(k)=i(k)·i(k−N)+q(k)·q(k−N) =cos {2πƒ_{d}/ƒ_{symb}+Δθ(k)}
w(k)=i(k−N)·q(k)−i(k)·q(k−N) =sin {2πƒ_{d}/ƒ_{symb}+Δθ(k)}
where f_{symb} is the symbol rate, N is the number of samples per baud, and Δθ(k) is the phase transition between the sample in the current symbol and the corresponding sample in the immediately preceding symbol.

5. The method of claim 1, further comprising the step of applying a symbol timing recovery algorithm to said digitized received signal.

6. A receiver that compensates for frequency offset in a received signal, comprising:
an analog-to-digital converter for digitizing said received signal; and
a differential detector to pre-process said digitized received signal.

7. The receiver of claim 6, further comprising a demodulator to demodulate said received signal to generate baseband signals for in-phase and quadrature-phase components.

8. The receiver of claim 6, wherein said frequency offset compensation corrects for a Doppler shift.

9. The receiver of claim 6, wherein said differential detector pre-processes said digitized received signal i(k) and q(k) with symbol time interval spacing as follows:
z(k)=i(k)·i(k−N)+q(k)·q(k−N) =cos {2πƒ_{d}/ƒ_{symb}+Δθ(k)}
w(k)=i(k−N)·q(k)−i(k)·q(k−N) =sin {2πƒ_{d}/ƒ_{symb}+Δθ(k)}
where f_{symb} is the symbol rate, N is the number of samples per baud, and Δθ(k) is the phase transition between the sample in the current symbol and the corresponding sample in the immediately preceding symbol.

10. The receiver of claim 6, further comprising a symbol timing recovery stage.

11. The receiver of claim 6, wherein said receiver is a Differential PSK TDMA mobile phone system.

12. The receiver of claim 6, wherein said receiver is a Personal Handy Phone System.

13. The receiver of claim 6, wherein said receiver is a data communication system with differental PSK modulation.

14. A receiver that compensates for frequency offset in a received signal, comprising:
an analog-to-digital converter for digitizing said received signal;
a memory; and
at least one processor, coupled to the memory, operative to:
pre-process said digitized received signal using a differential detection technique.

15. The receiver of claim 14, further comprising a demodulator to demodulate said received signal to generate baseband signals for in-phase and quadrature-phase components.

16. The receiver of claim 14, wherein said frequency offset compensation corrects for a Doppler shift.

17. The receiver of claim 14, wherein said differential detection technique pre-processes said digitized received signal i(k) and q(k) with symbol time interval spacing as follows:
z(k)=i(k)·i(k−N)+q(k)·q(k−N) =cos {2πƒ_{d}/ƒ_{symb}+Δθ(k)}
w(k)=i(k−N)·q(k)−i(k)·q(k−N) =sin {2πƒ_{d}/ƒ_{symb}+Δθ(k)}
where f_{symb} is the symbol rate, N is the number of samples per baud, and Δθ(k) is the phase transition between the sample in the current symbol and the corresponding sample in the immediately preceding symbol.

18. The receiver of claim 14, wherein said processor is further configured to perform symbol timing recovery.
